(19) United States
(12) Patent Application Publication
(10) Pub. No.: US 2026/0018477 A1
(43) Pub. Date: Jan. 15, 2026

(54) ELECTRONIC DEVICE AND MANUFACTURING METHOD THEREOF AND PACKAGE STRUCTURE

(71) Applicant: Innolux Corporation, Miaoli County (TW)

(72) Inventors: Te-Hsun Lin, Miaoli County (TW); Wen-Hsiang Liao, Miaoli County (TW); Yen-Fu Liu, Miaoli County (TW); Ting-Han Lin, Miaoli County (TW)

(73) Assignee: Innolux Corporation, Miaoli County (TW)

(21) Appl. No.: 19/227,514

(22) Filed: Jun. 4, 2025

Related U.S. Application Data
(60) Provisional application No. 63/668,776, filed on Jul. 9, 2024.

(30) Foreign Application Priority Data
Feb. 5, 2025 (CN) 202510129929.2

(51) Int. Cl. H01L 23/31; H01L 21/56; H01L 23/00; H01L 23/373; H01L 25/065

(52) U.S. Cl. CPC H01L 23/3128; H01L 21/568; H01L 23/3736; H01L 24/19; H01L 24/20; H01L 24/24; H01L 25/0655; H01L 2224/19; H01L 2224/215; H01L 2224/24137; H01L 2224/244; H01L 2924/3511; H01L 2924/3512

(57) ABSTRACT

An electronic device includes a first semiconductor component, a second semiconductor component, an encapsulation layer, and a circuit layer. The encapsulation layer has a first side, and the encapsulation layer surrounds the first semiconductor component and the second semiconductor component. The circuit layer is disposed on the first side of the encapsulation layer. The encapsulation layer has a first thickness, and the first semiconductor component has a second thickness. The first thickness is greater than the second thickness. A difference between the first thickness and the second thickness is greater than half of the first thickness and less than three times the second thickness. In a top view, the encapsulation layer has a first area, the first semiconductor component has a second area, the second semiconductor component has a third area, and a sum of the second area and the third area is greater than half of the first area.

### CROSS-REFERENCE TO RELATED APPLICATION

This application claims the priority benefit of U.S. provisional application Ser. No. 63/668,776, filed on Jul. 9, 2024, and China application serial no. 202510129929.2, filed on Feb. 5, 2025. The entirety of each of the above-mentioned patent applications is hereby incorporated by reference herein and made a part of this specification.

### BACKGROUND

### Technical Field

The present disclosure relates to an electronic device and manufacturing method and a package structure thereof, particularly to an electronic device that can have better structural reliability and manufacturing method and a package structure thereof.

### Description of Related Art

Electronic devices or semiconductor devices may be formed through panel-level package (PLP) process or wafer-level package (WLP) process. During the process, warpage occurs due to mismatched properties such as chemical shrinkage or the coefficient of thermal expansion coefficient of the encapsulation layer material. When the package structure is separated from the carrier substrate, due to the lack of support from the carrier substrate, the warpage of the package structure is drastically amplified, which in turn causes cracks in the encapsulation layer, thereby affecting the structural reliability of the product.

### SUMMARY

The present disclosure is directed to an electronic device having better structural reliability.

The present disclosure is directed to a manufacturing method of an electronic device for making the aforementioned electronic device, which can reduce process risks.

The present disclosure is directed to a package structure having better structural reliability.

In an embodiment of the disclosure, the electronic device includes a first semiconductor component, a second semiconductor component, an encapsulation layer, and a circuit layer. The second semiconductor component is adjacent to the first semiconductor component. The encapsulation layer has a first side, and the encapsulation layer surrounds the first semiconductor component and the second semiconductor component. The circuit layer is disposed on the first side of the encapsulation layer. The encapsulation layer has a first thickness, and the first semiconductor component has a second thickness. The first thickness is greater than the second thickness. A difference between the first thickness and the second thickness is greater than half of the first thickness and less than three times the second thickness. In a top view, the encapsulation layer has a first area, the first semiconductor component has a second area, the second semiconductor component has a third area, and a sum of the second area and the third area is greater than half of the first area.

In an embodiment of the disclosure, a manufacturing method of an electronic device includes providing a first semiconductor component and a second semiconductor component. The first semiconductor component is adjacent to the second semiconductor component. The manufacturing method of an electronic device includes forming an encapsulation layer to surround the first semiconductor component and the second semiconductor component. The encapsulation layer has a first side. The manufacturing method of the electronic device includes forming a circuit layer on the first side of the encapsulation layer. The encapsulation layer has a first thickness, the first semiconductor component has a second thickness, the first thickness is greater than the second thickness, and a difference between the first thickness and the second thickness is greater than half of the first thickness and less than three times the second thickness. In a top view, the encapsulation layer has a first area, the first semiconductor component has a second area, the second semiconductor component has a third area, and a sum of the second area and the third area is greater than half of the first area.

In an embodiment of the disclosure, the package structure includes a first semiconductor component, a second semiconductor component, and an encapsulation layer. The second semiconductor component is adjacent to the first semiconductor component. The encapsulation layer surrounds the first semiconductor component and the second semiconductor component. The encapsulation layer has a first thickness, and the first semiconductor component has a second thickness, where the first thickness is greater than the second thickness. The difference between the first thickness and the second thickness is greater than half of the first thickness and less than three times the second thickness. In a top view, the encapsulation layer has a first area, the first semiconductor component has a second area, the second semiconductor component has a third area, and the sum of the second area and the third area is greater than half of the first area.

Based on the above, in the embodiment of the present disclosure, the first thickness of the encapsulation layer is greater than the second thickness of the first semiconductor component, and the difference between the first thickness and the second thickness is greater than half of the first thickness and less than three times the second thickness. In a top view, the sum of the second area of the first semiconductor component and the third area of the second semiconductor component is greater than half of the first area of the encapsulation layer. By this design, the risk of warping of the package structure causing cracks in the encapsulation layer can be effectively reduced, thereby allowing the electronic device of the present disclosure to have better structural reliability.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic top view of a package structure according to an embodiment of the disclosure.

FIG. 1B is a schematic cross-sectional view taken along a line I-I depicted in FIG. 1A.

FIG. 2 illustrates a relationship diagram between the thickness from the back surface of the semiconductor component to the second side of the encapsulation layer and the warpage of the package structure.

FIG. 3 is a schematic cross-sectional view of an electronic device according to an embodiment of the disclosure.

FIG. 4A to FIG. 4F are schematic cross-sectional views of partial steps of a manufacturing method of an electronic device according to an embodiment of the disclosure.

FIG. 5A to FIG. 5E are schematic cross-sectional views of partial steps of a manufacturing method of an electronic device according to another embodiment of the disclosure.

FIG. 6 is a schematic cross-sectional view of an electronic device according to another embodiment of the disclosure.

FIG. 7A to FIG. 7C are schematic cross-sectional view of partial steps of a manufacturing method of an electronic device according to another embodiment of the disclosure.

FIG. 8A to FIG. 8C are schematic cross-sectional view of partial steps of a manufacturing method of an electronic device according to another embodiment of the disclosure.

### DESCRIPTION OF THE EMBODIMENTS

The disclosure may be understood by referring to the following detailed description in conjunction with the accompanying drawings. It should be noted that in order to facilitate understanding for the reader and to simplify the drawings, the plurality of drawings in the disclosure depict a portion of the electronic device, and certain components in the drawings are not drawn to actual scale. In addition, the quantity and the dimension of each component in the figures are for illustration, and are not intended to limit the scope of the disclosure.

Certain terms are used throughout the specification and the appended claims of the disclosure to refer to particular components. Those skilled in the art should understand that electronic equipment manufacturers may refer to the same components under different names. This article does not intend to distinguish between those components that have the same function but different names.

In the following specification and claims, words such as “containing” and “including” are open-ended words, so they should be interpreted as meaning “containing but not limited to . . . ”

In addition, relative terms, such as “below” or “bottom” and “above” or “top”, may be used in the embodiments to describe the relative relationship of one component to another component in the drawing. It will be understood that if the device in the figures is turned upside down, components described as being on the “lower” side would then be components described as being on the “upper” side.

In some embodiments of the disclosure, terms related to joining, connecting, such as “connecting”, “interconnecting”, etc., unless otherwise specified, may mean that two structures are in direct contact, or it may also mean that the two structures are not being directly (i.e., indirectly) contact, and there are other structures disposed between the two structures. Moreover, the terms of bonding and connecting may also include the case where both structures are movable or both structures are fixed. Moreover, the term “coupling” includes the transfer of energy between two structures via direct or indirect electrical connection, or the transfer of energy between two separate structures via mutual induction.

It should be understood that, when a component or film is referred to as being “on” or “connected to” another component or film, it may be directly on or directly connected to the another component or layer, alternatively, one or more intervening elements or layers may exist between them (non-direct case). In contrast, when a component is referred to as being “directly on” or “directly connected to” another component or layer, no intervening elements or layers are present between them.

The terms “about”, “equal”, “same” or “identical”, “substantially” or “roughly” are generally interpreted as being within 20% of a given value or range, or interpreted as being within 10%, 5%, 3%, 2%, 1%, or 0.5% of a given value or range. Furthermore, the phrases “range from a first value to a second value”, “range between a first value and a second value” indicate that the said range includes the first value, the second value, and other values between them.

In the disclosure, optical microscopy (OM), scanning electron microscopy (SEM), film thickness profiler (α-step), ellipsometer, or other suitable methods may be used to measure the area, width, thickness, or height of each component, or the distance or spacing between the components. Specifically, according to some embodiments, a scanning electron microscope may be used to obtain a cross-sectional structure image of the components to be measured, and measure the area, width, thickness, or height of each component, or the distance or spacing between the components. In the disclosure, the definition of roughness determination may be observed by SEM. On an uneven surface, it may be seen that the peaks and valleys of the surface undulation have a distance difference of 0.15 microns (μm) to 1 μm. Measurements of roughness determination may include the use of SEM, transmission electron microscope (TEM), etc. to observe the surface undulation at the same appropriate magnification, and to compare the undulation with a sample of unit length (for example, 10-μm), which is the roughness range thereof. Here, “appropriate magnification” means that at least one surface may have a roughness (Rz) or an average roughness (Ra) of at least 10 peaks and valleys visible under the field of view of this magnification.

As used herein, the terms “film” and/or “layer” may refer to any continuous or discontinuous structure and material (such as a material deposited by a method disclosed herein). For example, a film and/or a layer may include a two-dimensional material, a three-dimensional material, a nanoparticle, or even a partial or complete molecular layer, or a partial or complete atomic layer, or a cluster of atoms and/or molecules. The film or layer may include a material or a layer having pinholes, and may be at least partially continuous.

Although the terms first, second, third . . . may be used to describe various constituent components, the constituent components are not limited to these terms. The terms are used to distinguish a single constituent component from other constituent components in the specification. The same terms may be not used in the claims, but are replaced by first, second, third . . . in the order in which components are declared in the claims. Therefore, in the following specification, a first constituent component may be a second constituent component in the claims.

Unless otherwise defined, all terms (including technical and scientific terms) used herein have the same meaning as commonly understood by one of ordinary skill in the art to which this disclosure belongs. It may be understood that these terms, such as those defined in commonly used dictionaries, should be interpreted as having meaning consistent with the background or the context of the related techniques and the disclosure, and should not be interpreted in an idealized or overly formal manner, unless otherwise defined herein.

It should be noted that in the following embodiments, the technical features in several different embodiments may be replaced, recombined, and mixed to complete other embodiments without departing from the spirit of the disclosure.

An electronic device of the disclosure may include a power module, a semiconductor device, a semiconductor packaging device, a display device, an antenna device, a sensing device, a light-emitting device, or a tiling device, but the disclosure is not limited thereto. The electronic device may include a bendable or flexible electronic device. The electronic device may include an electronic component. The electronic component may include a semiconductor component, a passive component, an active component, or a combination of the above, such as an integrated circuit chip, a high bandwidth memory, a capacitor, a resistor, an inductor, a variable capacitor, a filter, a diode, a transistor, a sensor, a microelectromechanical system (MEMS), a liquid-crystal chip, etc., but the disclosure is not limited thereto. The diode may include a light-emitting diode (LED) or a non-light-emitting diode. The diode includes a P-N junction diode, a PIN diode, or a constant current diode. The LED may include, for example, an organic light-emitting diode (OLED), a mini LED, a micro LED, or a quantum dot light-emitting diode, fluorescence, phosphor, or other suitable materials, or a combination of the above, but the disclosure is not limited thereto. The sensor may include, for example, a capacitive sensor, an optical sensor, an electromagnetic sensor, a fingerprint sensor (FPS), a touch sensor, an antenna, or a pen sensor, but the disclosure is not limited thereto. The following uses a display device as an electronic device to explain the content of the disclosure, but the disclosure is not limited thereto. According to an embodiment of the disclosure, the provided manufacturing method of the electronic device may be applied, for example, to a wafer-level package (WLP) process or a panel-level package (PLP) process, and may adopt a chip-first process or a chip-last (RDL-first) process, which is explained in further detail below. The electronic device referred to in the disclosure may include system on package (SoC), system in package (SiP), antenna in package (AiP), co-packaged optics (CPO), or a combination of the above, but the disclosure is not limited thereto.

Hereinafter, reference will be made in detail to exemplary embodiments of the disclosure, and examples of the exemplary embodiments are illustrated in the figures. Wherever possible, the same reference numerals are used in the drawings and descriptions to refer to the same or like portions.

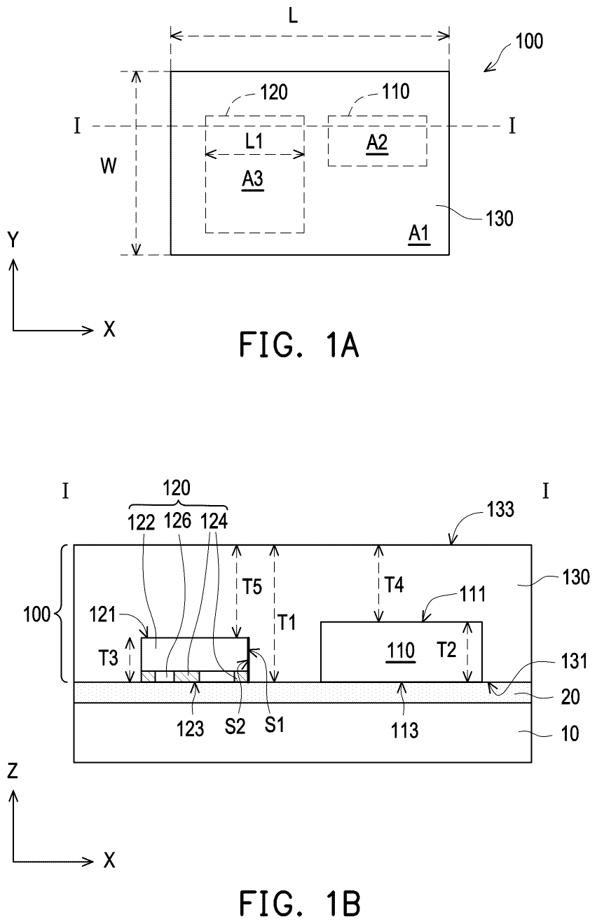

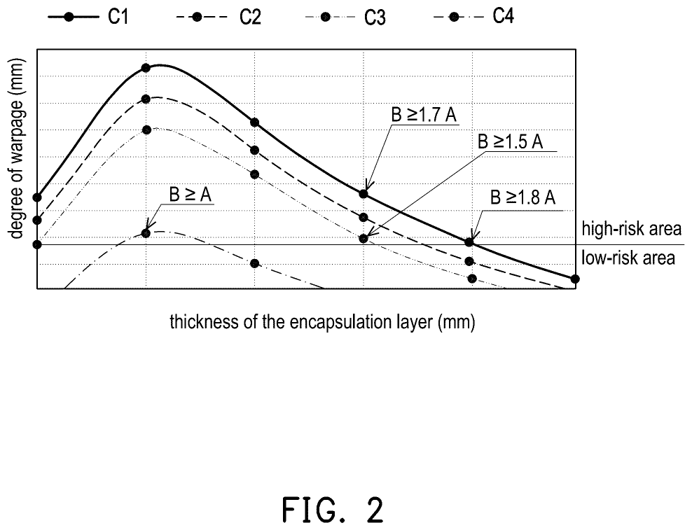

FIG. 1A is a schematic top view of a package structure according to an embodiment of the disclosure. FIG. 1B is a schematic cross-sectional view taken along a line I-I depicted in FIG. 1A. FIG. 2 illustrates a relationship diagram between the thickness from the back surface of the semiconductor component to the second side of the encapsulation layer and the warpage of the package structure.

With reference to FIG. 1A and FIG. 1B, in this embodiment, a package structure 100 includes a first semiconductor component 110, a second semiconductor component 120, and an encapsulation layer 130. The second semiconductor component 120 is adjacent to the first semiconductor component 110. The encapsulation layer 130 surrounds the first semiconductor component 110 and the second semiconductor component 120. The encapsulation layer 130 has a first thickness T1, and the first semiconductor component 110 has a second thickness T2, where the first thickness T1 is greater than the second thickness T2. A difference between the first thickness T1 and the second thickness T2 is greater than half of the first thickness T1 and less than three times the second thickness T2. In a top view, the encapsulation layer 130 has a first area A1, the first semiconductor component 110 has a second area A2, the second semiconductor component 120 has a third area A3, and a sum of the second area A2 and the third area A3 is greater than half of the first area A1.

Specifically, in this embodiment, the package structure 100 is disposed on a carrier substrate 10 through an adhesive layer 20, meaning that the carrier substrate 10 serves as a supporting structure and can be used to support the package structure 100. In another embodiment, the carrier substrate 10 may be, for example, quartz, glass, stainless steel, sapphire, other suitable materials, or combinations thereof, but not limited thereto. In another embodiment, the adhesive layer 20 may be a temporary adhesive layer, which may include thermal-type or optical-type release materials with adhesive properties, allowing subsequently formed work units, components, or film layers to be temporarily bonded to the adhesive layer 20. For example, the adhesive layer 20 may be a thermal release tape (HRT) or a light-to-heat-conversion (LTHC) release coating. When an optical-type release material is used to form the adhesive layer 20, the optical-type release material loses its adhesiveness when exposed to radiation such as ultra-violet (UV) light, allowing components or film layers formed on it to be peeled off from the adhesive layer 20. For instance, the adhesive layer 20 may be a UV glue.

Moreover, the second semiconductor component 120 is adjacent to the first semiconductor component 110. Herein, “adjacent to” refers to adjacency in the horizontal direction (such as the X direction). According to some embodiments, the distance between the first semiconductor component 110 and the second semiconductor component 120 may be greater than or equal to 0.2 times the first length L1 of the second semiconductor component 120 and less than or equal to 1.5 times the first length L1 of the second semiconductor component 120, thereby avoiding signal interference between semiconductor components, but not limited thereto. The second semiconductor component 120 of this embodiment includes at least one semiconductor unit (one semiconductor unit 122 is schematically shown). In another embodiment, a single semiconductor unit 122 may be, for example, a die or a component with a semiconductor structure, but not limited thereto. In another embodiment, the second semiconductor component 120 may include multiple stacked semiconductor units, and the stacked multiple semiconductor units may be, for example, memory (such as RAM), but not limited thereto. In another embodiment, the second semiconductor component 120 may further include conductive pads 124 and an insulation layer 126 located between the conductive pads 124. The conductive pads 124 and the insulation layer 126 located between the conductive pads 124 of the second semiconductor component 120 may contact the adhesive layer 20. In another embodiment, the second semiconductor component 120 may include multiple stacked semiconductor units 122, conductive pads 124, and an insulation layer 126 located between the conductive pads 124. The second thickness T2 of the first semiconductor component 110, as viewed in cross-section, is the thickness of the first semiconductor component 110 surrounded by the encapsulation layer 130, and this thickness may be measured along the Z direction. The third thickness T3 of the second semiconductor component 120, as viewed in cross-section, is the thickness of the second semiconductor component 120 surrounded by the encapsulation layer 130, and this thickness may be measured along the Z direction. In another embodiment, the second thickness T2 of the first semiconductor component 110 is greater than the third thickness T3 of the second semiconductor component 120. In another embodiment, the first semiconductor component 110 may be, for example, the thickest semiconductor component in the package structure 100.

The encapsulation layer 130 has a first side 131 and a second side 133 opposite to each other, where the first side 131 contacts the adhesive layer 20. An active surface 113 of the first semiconductor component 110 and an active surface 123 of the second semiconductor component 120 are substantially coplanar with the first side 131 of the encapsulation layer 130. In another embodiment, a back surface 111 of the first semiconductor component 110 and a back surface 121 of the second semiconductor component 120 are covered by the encapsulation layer 130. The encapsulation layer 130 surrounds the first semiconductor component 110 and the second semiconductor component 120. Herein, the encapsulation layer 130 “surrounds” the semiconductor components (e.g., the first semiconductor component 110 or the second semiconductor component 120), which may refer to a perspective view (i.e., orthographic projection) in the top view direction where the encapsulation layer 130 surrounds the semiconductor components, and in a cross-sectional view, “a side surface S1 of the encapsulation layer 130 is adjacent to a side surface S2 of the semiconductor components”. In other words, “the encapsulation layer 130 may include at least one accommodating space for accommodating the semiconductor components”. As shown in FIG. 1B, the encapsulation layer 130 may directly contact the side surfaces of the first semiconductor component 110 and the second semiconductor component 120. The encapsulation layer 130 may provide waterproof effect for the first semiconductor component 110 and the second semiconductor component 120, thereby improving the reliability of the package structure 100. In another embodiment, a ratio of the coefficient of thermal expansion of the encapsulation layer 130 to the coefficient of thermal expansion of a single semiconductor unit 122 is between 1.2 and 3. Through this design, the risk of separation or cracking between the encapsulation layer 130 and the semiconductor components may be reduced. In another embodiment, the encapsulation layer 130 may include any suitable organic or inorganic material, such as epoxy molding compound (EMC), silicon oxide (SiOₓ), silicon nitride (SiNₓ), silicon oxynitride (SiOₓN_{y}), but not limited thereto.

Please refer again to FIG. 1B, the first thickness T1 of the encapsulation layer 130 is the vertical distance (e.g., along the Z direction) from the second side 133 to the first side 131 of the encapsulation layer 120. Since the first semiconductor component 110 and the second semiconductor component 120 may be directly bonded to the adhesive layer 20 and substantially flush with the first side 131 of the encapsulation layer 130, the second thickness T2 of the first semiconductor component 110 may also be the vertical distance from the back surface 111 of the first semiconductor component 110 to the first side 131 of the encapsulation layer 130, and the third thickness T3 of the second semiconductor component 120 may also be the vertical distance from the back surface 121 of the second semiconductor component 120 to the first side 131 of the encapsulation layer 130. In another embodiment, the second thickness T2 of the first semiconductor component 110 may be less than the first thickness T1 of the encapsulation layer 130, and the third thickness T3 of the second semiconductor component 120 may be less than the second thickness T2 of the first semiconductor component 110. In another embodiment, the third thickness T3 of the second semiconductor component 120 may be less than or equal to the first thickness T1 of the encapsulation layer 130.

On the other hand, the vertical distance from the back surface 111 of the first semiconductor component 110 to the second side 133 of the encapsulation layer 130 is a fourth thickness T4, while the vertical distance from the back surface 121 of the second semiconductor component 120 to the second side 133 of the encapsulation layer 130 is a fifth thickness T5. Herein, the fourth thickness T4 equals the difference between the first thickness T1 and the second thickness T2, while the fifth thickness T5 equals the difference between the first thickness T1 and the thickness T3. More specifically, the fourth thickness T4 is a localized thickness of the encapsulation layer 130. Herein, “localized” refers to the portion of the encapsulation layer 130 that falls within the orthogonal projection of the first semiconductor component 110, which may be measured from the back surface 111 of the first semiconductor component 110 along the normal direction to the second side 133 of the encapsulation layer 130. The fourth thickness T4 may be greater than the second thickness T2 of the first semiconductor component 110 and less than three times the first thickness T2 of the first semiconductor component 110. The fifth thickness T5 is the localized thickness of the encapsulation layer 130. Herein, “localized” refers to the portion of the encapsulation layer 130 that falls within the orthogonal projection of the second semiconductor component 120, which may be measured from the back surface 121 of the second semiconductor component 120 along the normal direction to the second side 133 of the encapsulation layer 130. In another embodiment, the fourth thickness T4 may be less than the fifth thickness T5.

Please refer again to FIG. 1A, in a top view, the first semiconductor component 110, the second semiconductor component 120, and the encapsulation layer 130 are rectangular in shapes. The encapsulation layer 130 has a first area A1, where the first area A1 equals the length L multiplied by the width W. Herein, the sum of the second area A2 of the first semiconductor component 110 and the third area A3 of the second semiconductor component 120 may be greater than half of the first area A1 of the encapsulation layer 130. “The second area A2” and “the third area A3” refer to the maximum length L in one direction (e.g., X direction) multiplied by the maximum width W in a second direction (e.g., Y direction) of one of the semiconductor components, where the first direction is perpendicular to the second direction.

Please refer to FIG. 2, in this relationship diagram, B and A show different degrees of warpage of the encapsulation layer at different ratios. B represents the vertical distance from the semiconductor component to the second side of the encapsulation layer (such as the fourth thickness T4 in FIG. 1B), while A represents the thickness of the semiconductor component (such as the second thickness T2 in FIG. 1B). Curves C1, C2, C3, and C4 represent different ratios of semiconductor components per unit area, for example, the ratio of semiconductor components in the package structure of curve C1 may be greater than that in the package structure of curve C4. That is, the ratio of the orthogonal projection area of the semiconductor component on the encapsulation layer to the area of the encapsulation layer. Therefore, it is necessary to select the relationship between B and A that is close to or falls in a low risk area to make the parameters, so as to improve the yield of the packaging structure 100. As shown in FIG. 2, when the orthogonal projection area of the semiconductor component on the encapsulation layer 130 (please refer to FIG. 1B) is greater than or equal to 50% of the area of the encapsulation layer 130 (please refer to FIG. 1B), B≥1.5 A may reduce the problem of cracking of the encapsulation layer 130 (please refer to FIG. 1B) due to warpage of the package structure 100, allowing the package structure to have better structural reliability.

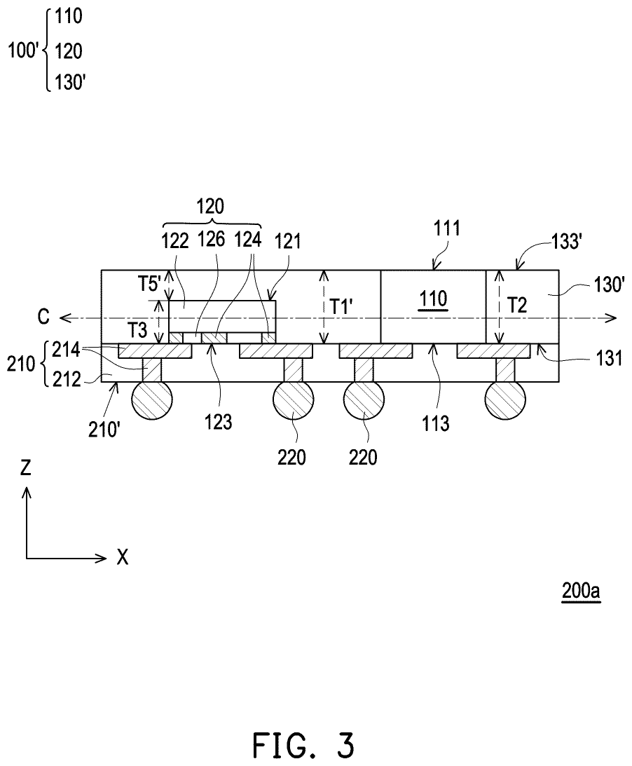

In another embodiment, the coefficient of thermal expansion of the semiconductor component may be smaller than the coefficient of thermal expansion of the encapsulation layer. For example, the coefficient of thermal expansion of the semiconductor component may be 5.43, while the coefficient of thermal expansion of the encapsulation layer may be 7. At this time, when the thickness of the semiconductor component is less than half the thickness of the encapsulation layer, it may have better warpage resistance. In other words, half the height of the package structure (i.e., the center line C) should fall on the side of the encapsulation layer 130. Furthermore, in a schematic cross-sectional view (please refer to FIG. 3), the center line C of the package structure may be perpendicular to the Z direction, and the extension direction of the center line C of the package structure may pass through the encapsulation layer 130. Through the above design, the semiconductor component may have better warpage resistance, but not limited thereto. The indicated center line C in this disclosure refers to the distance from the second side 133′ of the encapsulation layer 130 to the center line C being equal to the distance from one side 210′ of the circuit layer 210 to the center line C, where the one side 210′ of the circuit layer 210 is a surface away from the second side 133′ of the encapsulation layer 130.

It should be noted here that the following embodiments use the reference numbers and part of the content of the foregoing embodiments. The same numbers are used to indicate the same or similar devices, and the description of the same technical content is omitted. Regarding the description of the omitted parts, reference may be made to the foregoing embodiments, which will not be repeated in the following embodiments.

FIG. 3 is a schematic cross-sectional view of an electronic device according to an embodiment of the disclosure. With reference to FIG. 1B and FIG. 3, in this embodiment, the electronic device 200a can include a package structure 100′ and a circuit layer 210. Specifically, the electronic device 200a can include the first semiconductor component 110, the second semiconductor component 120, an encapsulation layer 130′, and a circuit layer 210. The second semiconductor component 120 is adjacent to the first semiconductor component 110. The encapsulation layer 130′ has a first side 131, and the encapsulation layer 130′ surrounds the first semiconductor component 110 and the second semiconductor component 120. The first semiconductor component 110, the second semiconductor component 120, and the encapsulation layer 130′ may define the package structure 100′. The circuit layer 210 is disposed on the first side 131 of the encapsulation layer 130′. The encapsulation layer 130′ has a first thickness T1′, and the first semiconductor component 110 has a second thickness T2. The first thickness T1′ is equal to the second thickness T2. In other words, the back side 111 of the first semiconductor component 110 is exposed outside the encapsulation layer 130′. From a top view, the sum of the second area (such as A2 in FIG. 1A) of the first semiconductor component 110 and the third area (such as A3 in FIG. 1A) of the second semiconductor component 120 may be greater than half of the first area (such as A1 in FIG. 1A) of the encapsulation layer 130′. In another embodiment, the fifth thickness T5′ from the back side 121 of the second semiconductor component 120 to the second side 133′ of the encapsulation layer 130′ can be greater than half of the third thickness T3 and less than three times the third thickness T3, which may prevent warpage. In another embodiment, the second thickness T2 may optionally be less than the first thickness T1′. In other words, the back side 111 of the first semiconductor component 110 may also be covered by the encapsulation layer 130, and the difference between the first thickness T1′ and the second thickness T2 may be greater than the second thickness T2.

The circuit layer 210 of this embodiment is disposed on the first side 131 of the encapsulation layer 130′, and the stacking direction of the insulation layer 212 and the conductive layer 214 of the circuit layer 210 can be along the Z direction and can be stacked into any suitable structure. In other words, the first side 131 of the encapsulation layer 130′ is the side on which the circuit layer 210 is disposed, while the second side 133′ is the side facing the first side 131 and away from the circuit layer 210. In another embodiment, the circuit layer 210 may directly contact the first side 131 of the encapsulation layer 130′, the active surface 113 of the first semiconductor component 110, and the active surface 123 of the second semiconductor component 120, and the first semiconductor component 110 and the second semiconductor component 120 may be electrically connected to the circuit layer 210. In another embodiment, the conductive layer 214 may exemplify routes, conductive through holes, conductive blind holes, pads, or combinations thereof, as long as it has conductive functionality, all of which are referred to as conductive portions in this disclosure. In another embodiment, the conductive layer 214 may exemplify connecting portions and traces, where the connecting portions refer to the portions located in the openings of the insulation layer or the encapsulation layer, used for signal transmission in the vertical direction (e.g., Z direction), while the traces refer to the portions except for the connecting portions, used for signal transmission in the horizontal direction (e.g., X or Y direction). In another embodiment, the material of the conductive layer 214 may exemplify copper (Cu), aluminum (Al), nickel (Ni), molybdenum (Mo), titanium (Ti), gold (Au), tin (Sn), gallium (Ga), ruthenium (Ru), tantalum (Ta), alloys or combinations of the above materials, or other suitable materials, but not limited thereto. In another embodiment, the material of the insulation layer 212 may exemplify build-up film, polyimide, epoxy, silicon dioxide, silicon nitride, solder resist, or combinations thereof, but not limited thereto.

In another embodiment, the circuit layer 210 may also be referred to as a redistribution layer. The redistribution layer may be electrically connected to chips, semiconductor components, or other electronic components through solder balls or other bonding components. The redistribution layer may include at least one dielectric layer (or insulation layer) and at least one conductive layer alternately stacked along the Z direction. Through at least one dielectric layer and at least one conductive layer, the route may be redistributed and/or the fan-out or fan-in area of the route may be increased, or different electronic components may be electrically connected to each other through the redistribution layer. For example, the pitch between two adjacent contact pads at the end of the redistribution layer in contact with the semiconductor component or electronic component may be less than or equal to the pitch between two adjacent contact pads at the end of the redistribution layer away from the semiconductor component or electronic component. Therefore, the redistribution layer may adjust the route fan-out condition or electrically connect a circuit structure/electronic component with a first pitch to a circuit structure/electronic component with a second pitch, but not limited thereto. The method of forming the redistribution layer may include using photolithography process, surface treatment process, laser process, electroplating process, deposition process, or other processes to form at least one dielectric layer and at least one conductive layer. The surface treatment process includes roughening or activating the surface of the dielectric layer or the conductive layer to enhance its adhesion ability. For example, by increasing the surface roughness, the bonding strength with subsequent film layers may be enhanced.

In addition, the electronic device 200a of this embodiment also includes bonding components 220, disposed on the side of the circuit layer 210 away from the encapsulation layer 130, wherein the circuit layer 210 is located between the encapsulation layer 130 and the bonding components 220, and the bonding components 220 are electrically connected to the circuit layer 210. The electronic device 200a may be electrically connected to external circuits through the bonding components 220. In another embodiment, the material of the bonding components 220 may be, for example, tin, nickel, gold, silver, palladium, copper, gallium, alloys thereof, or combinations thereof, but not limited thereto. In another embodiment, the bonding components 220 may be solder balls, for example, but not limited thereto.

In brief, in this embodiment, the first thickness T1′ of the encapsulation layer 130′ is greater than or equal to the second thickness T2 of the first semiconductor component 110. When the first thickness T1′ is greater than the second thickness T2, the difference between the first thickness T1′ and the second thickness T2 is greater than half of the first thickness T1′ and less than three times the second thickness T2. In a top view, the sum of the second area of the first semiconductor component 110 and the third area of the second semiconductor component 120 is greater than half of the first area of the encapsulation layer 130′. When the first thickness T1′ is equal to the second thickness T2, the fifth thickness T5′ of the encapsulation layer 130′ may be greater than half of the third thickness T3 and less than three times the third thickness T3. In a top view, the sum of the second area A2 of the first semiconductor component 110 and the third area A3 of the second semiconductor component 120 may be greater than half of the first area A1 of the encapsulation layer 130′. Through this design, the risk of cracking in the encapsulation layer 130′ due to warpage when the package structure 100′ is turned upside down and separated from the carrier substrate may be effectively reduced/mitigated, allowing the electronic device 200a disclosed herein to have better structural reliability.

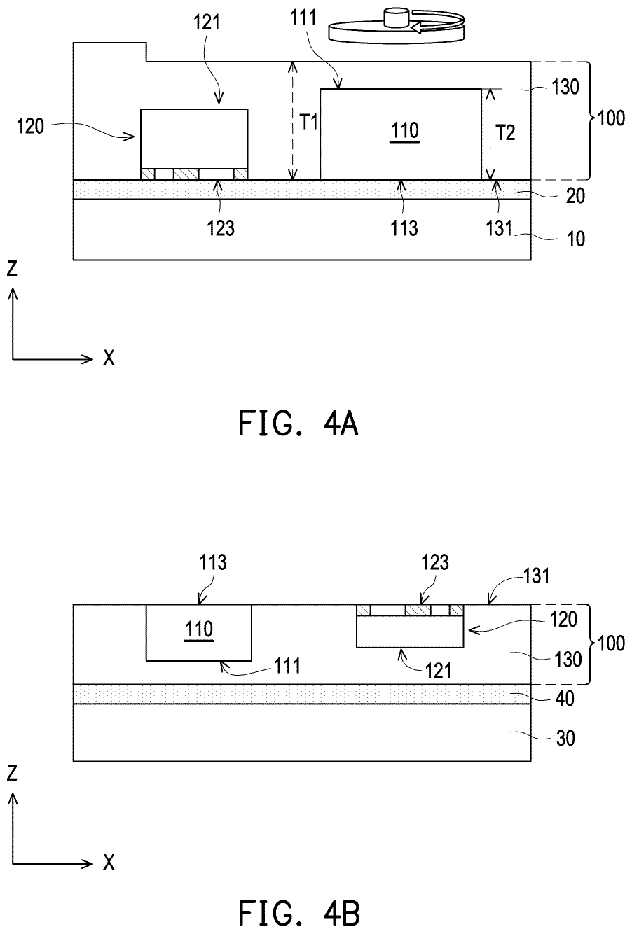

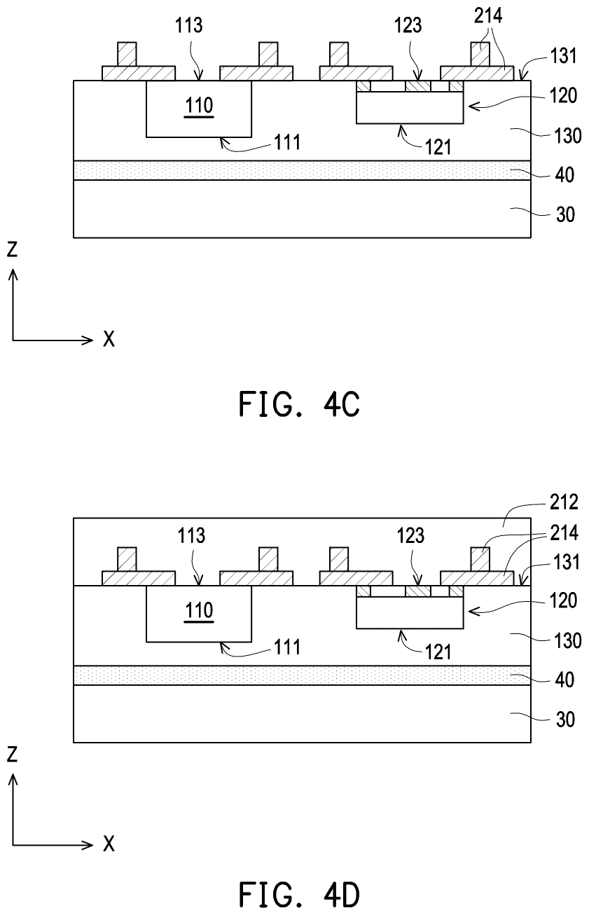

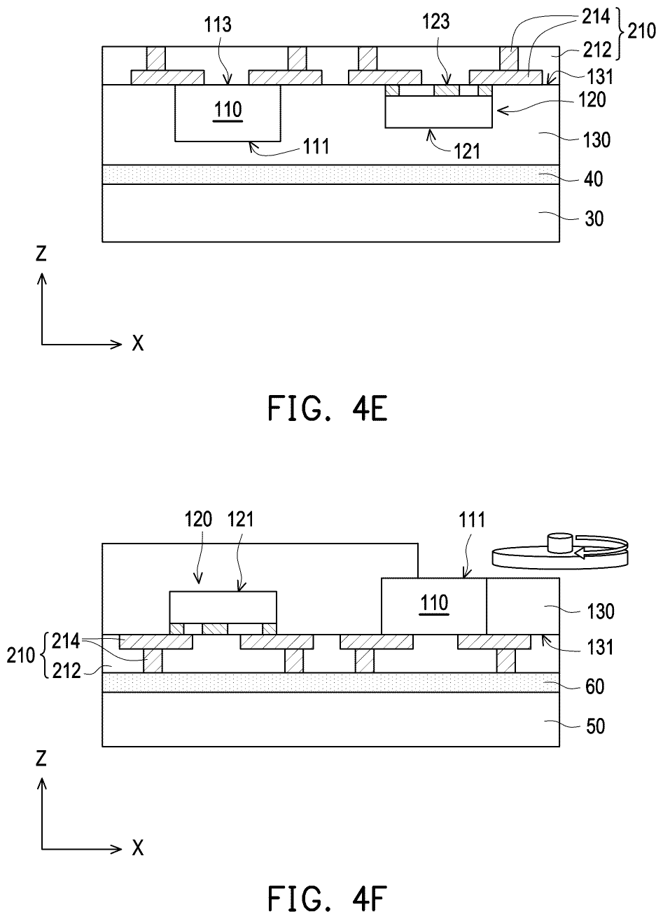

FIG. 4A to FIG. 4F are schematic cross-sectional views of partial steps of a manufacturing method of an electronic device according to an embodiment of the disclosure. Refer to FIG. 4A, regarding the manufacturing method of the electronic device in this embodiment, firstly, a first semiconductor component 110 and a second semiconductor component 120 are provided. The first semiconductor component 110 is adjacent to the second semiconductor component 120. Then, the first semiconductor component 110 and the second semiconductor component 120 are disposed on a carrier substrate 10 through an adhesive layer 20. Herein, the carrier substrate 10 may serve as a supporting structure to support the first semiconductor component 110 and the second semiconductor component 120. In another embodiment, the carrier substrate 10 may be, for example, quartz, glass, stainless steel, sapphire, other suitable materials, or combinations thereof, but not limited thereto. According to some embodiments, the release method of the adhesive layer 20 may include photo-release, thermal release, other suitable methods, or combinations of any two of the above. For example, depending on the different release methods, the adhesive layer 20 may be paired with different types of carrier substrates. For instance, a photo-release type adhesive layer 20 may be paired with a transparent glass substrate, while a thermal release type adhesive layer 20 may be paired with a steel plate. The adhesive layer 20 may include, for example, ultraviolet (UV) release film, heat release tape (HRT), other suitable materials, or combinations of any two of the above. By setting up the adhesive layer 20 on the carrier substrate 10, the package structure can be effectively separated.

In another embodiment, the first semiconductor component 110 and the second semiconductor component 120 may be dispose on the carrier substrate 10 with their active surfaces 113, 123 facing towards the carrier substrate 10. Then, an encapsulation layer 130 is formed to surround the first semiconductor component 110 and the second semiconductor component 120, where the encapsulation layer 130 may selectively expose the back surface 111 of the first semiconductor component 110 and the top surface 121 of the second semiconductor component 120, which may be referred to as a face-down process. The encapsulation layer 130 is formed on the adhesive layer 20 and covers the first semiconductor component 110 and the second semiconductor component 120. Next, the encapsulation layer 130 is ground to make the encapsulation layer 130 have a flat surface. At this point, the encapsulation layer 130 still covers the back surface 111 of the first semiconductor component 110 and the back surface 121 of the second semiconductor component 120. The encapsulation layer 130 has a first side 131 and a second side 133 opposite to each other, where the first side 131 contacts the adhesive layer 20. The encapsulation layer 130 has a first thickness T1, and the first semiconductor component 110 has a second thickness T2, where the first thickness T1 is greater than the second thickness T2. The difference between the first thickness T1 and the second thickness T2 is greater than half of the first thickness T1 and less than three times the second thickness T2. At this point, the package structure 100 in FIG. 1B is completed. As shown in FIG. 1A, from a top view, the encapsulation layer 130 has a first area A1, the first semiconductor component 110 has a second area A2, the second semiconductor component 120 has a third area A3, and the sum of the second area A2 and the third area A3 is greater than half of the first area A1.

Next, please refer to FIG. 4B, after forming the package structure 100 through a molding process, the package structure 100 is turned upside down and disposed on the carrier substrate 30 through the adhesive layer 40. At this time, the carrier substrate 10 and the adhesive layer 20 thereon are removed to expose the first side 131 of the encapsulation layer 130, the active surface 113 of the first semiconductor component 110, and the active surface 123 of the second semiconductor component 120.

Next, please refer to FIG. 4C, a conductive layer 214 is formed on the first side 131 of the encapsulation layer 130 to electrically connect the active surfaces of the first semiconductor component 110 and the second semiconductor component 120. In another embodiment, the conductive layer 214 may be, for example, routes, conductive through holes, conductive blind holes, pads, or combinations thereof. As long as it has conductive functionality, it falls within the conductive portion described in this disclosure. In another embodiment, the conductive layer 214 may include, for example, connecting portions and traces, where the connecting portion 214a refers to the portion located in the openings of the insulation layer or encapsulation layer, while the trace 214b refers to the portion outside the connecting portion 214a. In another embodiment, the material of the conductive layer 214 may be, for example, copper (Cu), aluminum (Al), nickel (Ni), molybdenum (Mo), titanium (Ti), gold (Au), tin (Sn), gallium (Ga), ruthenium (Ru), tantalum (Ta), alloys or combinations of the above materials, or other suitable materials, but not limited thereto.

Next, please refer to FIG. 4D, an insulation layer 212 is formed on the first side 131 of the encapsulation layer 130 to cover the conductive layer 214 and the active surfaces of the first semiconductor component 110 and the second semiconductor component 120.

In another embodiment, the material of the insulation layer 212 may be, for example, build-up film, polyimide, epoxy, silicon dioxide, silicon nitride, solder resist, or combinations thereof, but not limited thereto.

Next, please refer to FIG. 4E, the insulation layer 212 is ground to expose the conductive layer 214, where the insulation layer 212 and the conductive layer 214 define the circuit layer 210. At this point, the circuit layer 210 is formed on the first side 131 of the encapsulation layer 130, where the circuit layer 210 is electrically connected to the first semiconductor component 110 and the second semiconductor component 120.

Next, please refer to FIG. 4F, the structure shown in FIG. 4E is turned upside down and disposed on the carrier substrate 50 through the adhesive layer 60.

Afterwards, please referring to both FIG. 4F and FIG. 3, the encapsulation layer 130 is ground to form the second side 133′ of the encapsulation layer 130′. This grinding process may optionally expose the back surface 111 of the first semiconductor component 110 and the back surface 121 of the second semiconductor component 120, or may optionally expose only the back surface 111 of the first semiconductor component 110, or neither of the aforementioned semiconductor components may be exposed.

Finally, please refer again to FIG. 3, bonding components 220 are formed on the circuit layer 210, where the circuit layer 210 is located between the encapsulation layer 130′ and the bonding components 220, and the bonding components 220 are electrically connected to the circuit layer 210. The electronic device 200a may be electrically connected to external circuits through the bonding components 220. At this point, the manufacturing of the electronic device 200a is completed.

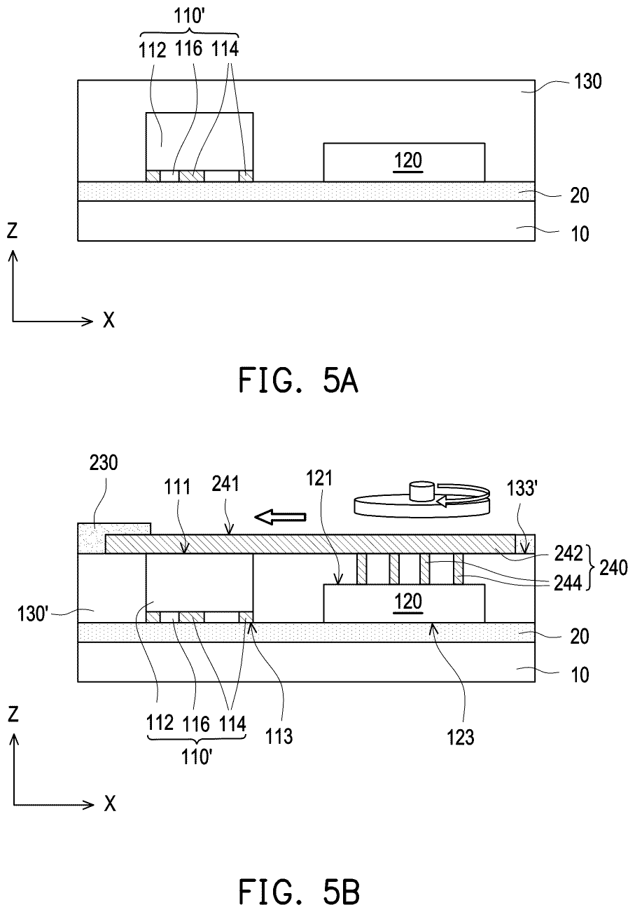

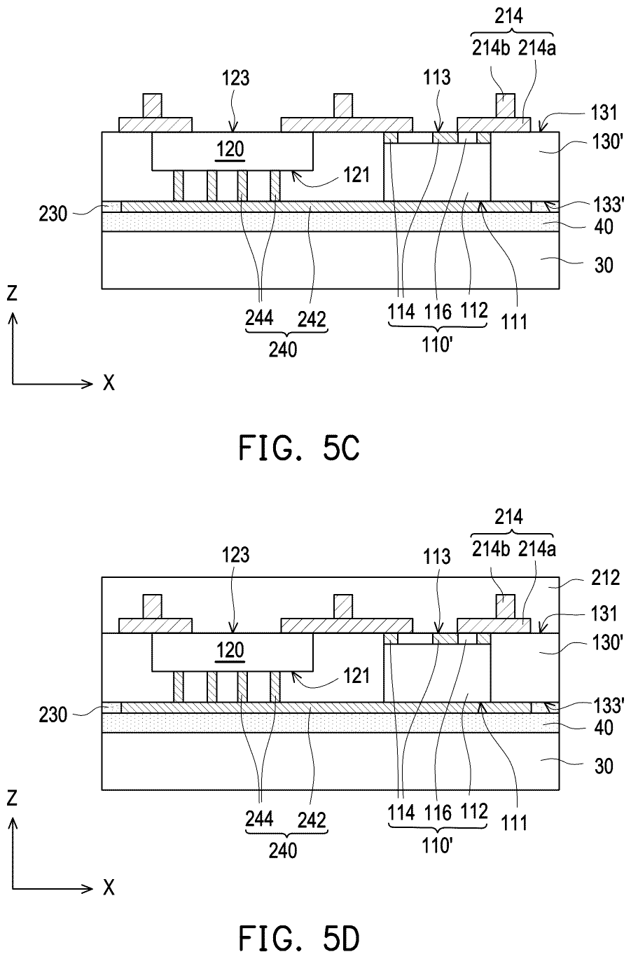

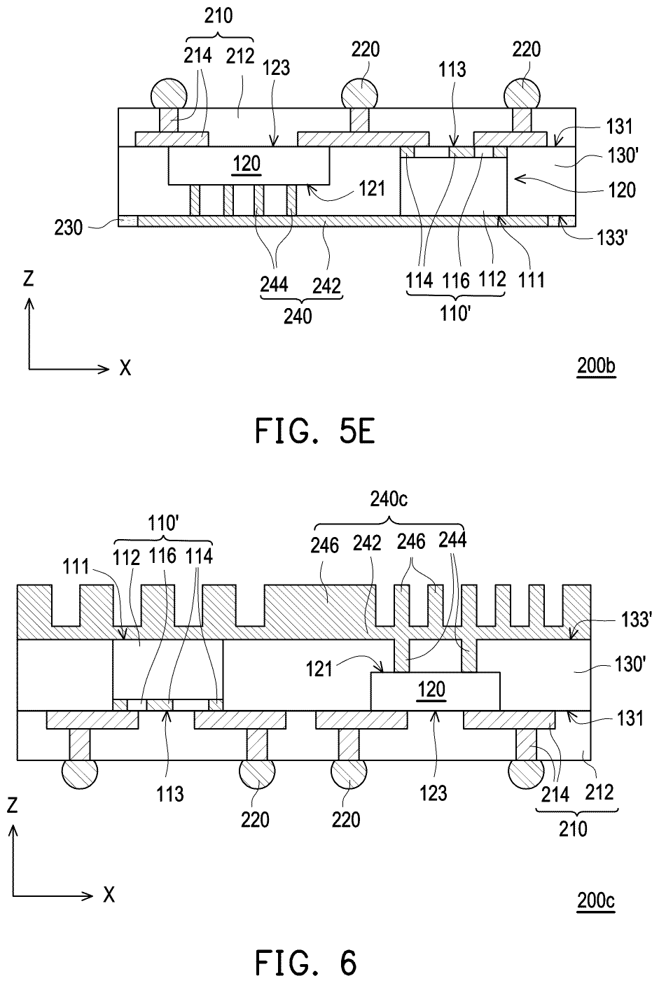

FIG. 5A to FIG. 5E are schematic cross-sectional views of partial steps of a manufacturing method of an electronic device according to another embodiment of the disclosure. Refer to FIG. 5A, regarding the manufacturing method of the electronic device in this embodiment, firstly, a first semiconductor component 110′ and a second semiconductor component 120 are provided. The first semiconductor component 110′ is adjacent to the second semiconductor component 120. The first semiconductor component 110′ in this embodiment includes a semiconductor unit 112, conductive pads 114, and an insulation layer 116 located between the conductive pads 114. Next, the first semiconductor component 110′ and the second semiconductor component 120 are disposed on a carrier substrate 10 through an adhesive layer 20. Then, an encapsulation layer 130 is formed to surround the first semiconductor component 110′ and the second semiconductor component 120. The encapsulation layer 130 is formed on the adhesive layer 20 and covers the first semiconductor component 110′ and the second semiconductor component 120.

Next, referring to both FIG. 5A and FIG. 5B, the encapsulation layer 130 is ground to expose the back surface 111 of the first semiconductor component 110′. Then, the encapsulation layer 130′ is patterned and a heat-conducting structure 240 is provided, where the heat-conducting structure 240 is disposed on the second side 133′ of the encapsulation layer 130′ and directly contacts the back surface 111 of the first semiconductor component 110′. In another embodiment, the heat-conducting structure 240 includes a main portion 242 and multiple extending portions 244, where the extending portions 244 connect to the main portion 242 and penetrate through the encapsulation layer 130′ to contact the back surface 121 of the second semiconductor component 120. In another embodiment, the orthographic projection area of the main portion 242 on the encapsulation layer 130′ is smaller than the area of the encapsulation layer 130′. In another embodiment, the orthographic projection area of the main portion 242 on the encapsulation layer 130′ completely covers the orthographic projections of the first semiconductor component 110′ and the second semiconductor component 120 on the encapsulation layer 130′. In another embodiment, the material of the heat-conducting structure 240 may include epoxy resin, die attach film (DAF), thermal interface material (TIM), other suitable adhesive materials, or combinations thereof, but not limited thereto. In another embodiment, the heat-conducting structure 240 may contact a surface of the semiconductor components, and the heat-conducting structure 240 may include materials with heat dissipation functions, such as silicone sheets, metals, graphene, silicon carbide, diamond, but not limited thereto. The heat-conducting structure 240 may include adhesive materials with heat-dissipating particles, such as epoxy resin containing graphite particles or epoxy resin containing ceramic heat-dissipating particles, but not limited thereto. In another embodiment, the material of the heat-conducting structure 240 may be a conductive material, for example, copper. In another embodiment, the material of the heat-conducting structure 240 includes conductive materials, i.e., it may conduct electricity, so that both sides of the semiconductor components may have the function of receiving or transmitting signals. In other words, both the first side 131 and the second side 133′ of the encapsulation layer 130′ are adjacent to circuits/conductive layers. The heat transfer coefficient of the heat-conducting structure 240 is greater than that of the encapsulation layer 130′, for example, the heat dissipation coefficient of the heat-conducting structure 240 may range from 20 W/m·K to 500 W/m·K.

Next, referring to FIG. 5B again, an insulation layer 230 is provided to cover the heat-conducting structure 240. Then, the insulation layer 230 is ground to expose the top surface 241 of the heat-conducting structure 240. Herein, the insulation layer 230 has a protective function to protect the side surface of the heat-conducting structure 240.

Next, referring to both FIG. 5B and FIG. 5C, the structure in FIG. 5B is turned upside down and disposed on a carrier substrate 30 through an adhesive layer 40. At this time, the carrier substrate 10 and the adhesive layer 20 thereon are removed to expose the active surface 113 of the first semiconductor component 110′ and the active surface 123 of the second semiconductor component 120. Then, a conductive layer 214 is formed on the first side 131 of the encapsulation layer 130 to electrically connect the active surface 113 of the first semiconductor component 110′ and the active surface 123 of the second semiconductor component 120. Please refer to FIG. 5C. In this embodiment, a part of the trace 214b of the conductive layer 214 may electrically connect both the first semiconductor component 110′ and the second semiconductor component 130 simultaneously as needed, but not limited thereto.

Thereafter, referring to FIG. 5D, an insulation layer 212 is formed on the first side 131 of the encapsulation layer 130′ to cover the conductive layer 214, the active surface 113 of the first semiconductor component 110′, and the active surface 123 of the second semiconductor component 120.

Next, referring to both FIG. 5D and FIG. 5E, the insulation layer 212 is ground to expose at least a portion of the conductive layer 214, wherein the insulation layer 212 and the conductive layer 214 define a circuit layer 210. At this point, the circuit layer 210 is formed on the first side 131 of the encapsulation layer 130′, wherein the circuit layer 210 is electrically connected to the first semiconductor component 110′ and the second semiconductor component 120.

Finally, referring to FIG. 5E, bonding components 220 are formed on the circuit layer 210, wherein the circuit layer 210 is located between the encapsulation layer 130′ and the bonding components 220, and the bonding components 220 are in contact with the circuit layer 210 and electrically connected to the conductive layer 214. The electronic device 200b may be electrically connected to an external circuit through the bonding components 220. At this point, the manufacturing of the electronic device 200b is completed.

FIG. 6 is a schematic cross-sectional view of an electronic device according to another embodiment of the disclosure. With reference to both FIG. 5E and FIG. 6, the electronic device 200c of this embodiment is similar to the electronic device 100b depicted in FIG. 5E, while the difference therebetween lies in that the heat-conducting structure 240c in this embodiment includes multiple heat dissipation fin portions 246 in addition to the main portion 242 and the extension portions 244. In another embodiment, the main portion 242 may contact the second side 133′ of the encapsulation layer 130′, or selectively cover the second side 133′ of the encapsulation layer 130′, and the heat dissipation fin portions 246 are dispersedly disposed on the side of the main portion 242 relatively far from the extension portion 244. In another embodiment, the cross-sectional shape of the heat dissipation fin portions 246 may be, for example, rectangular, square, rectangular, trapezoidal, triangular, semi-circular, elliptical, arc-shaped, or a combination of the above shapes, which may increase the heat dissipation surface area. In one embodiment, the main portion 242, the extension portions 244, and the heat dissipation fin portions 246 may be an integrally formed structure, but not limited thereto.

In the manufacturing process, the heat-conductive structure 240c can be processed between the steps depicted in FIG. 5B and FIG. 5C. During this phase, the main portion 242 of the heat-conductive structure 240c undergoes patterning to form a heat-conductive structure 240c with heat dissipation fin portions 246. Alternatively, between the steps of FIG. 5D to FIG. 5E, the structure of FIG. 5D may first be turned upside down onto another carrier substrate (not shown in the figure), the carrier substrate 30 and the adhesive layer 40 thereon may be removed to expose the main portion 242 of the heat-conducting structure 240, then the main portion 242 may be patterned to form the heat-conducting structure 240c with heat dissipation fin portions 246. Thereafter, the aforementioned structure may be again turned upside down onto another carrier substrate (not shown in the figure) and the insulation layer 212 may be ground to expose the conductive layer 214. Alternatively, after the step of FIG. 5E, the main portion 242 of the heat-conducting structure 240c may be patterned to form the heat-conducting structure 240c with heat dissipation fin portions 246. Finally, following the steps of FIG. 5E, the manufacturing of the electronic device 200c is completed.

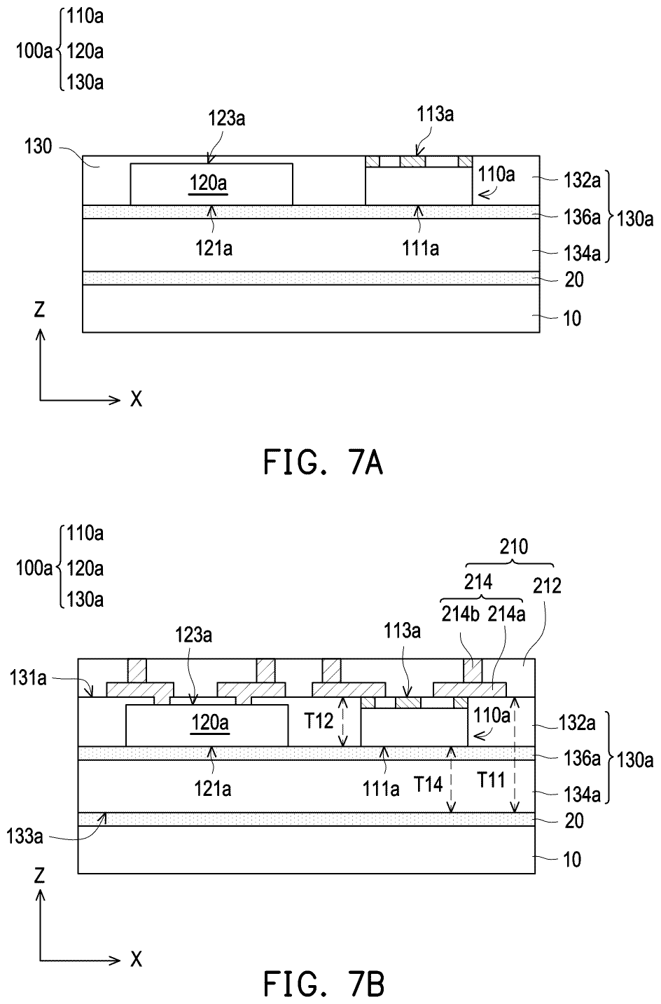

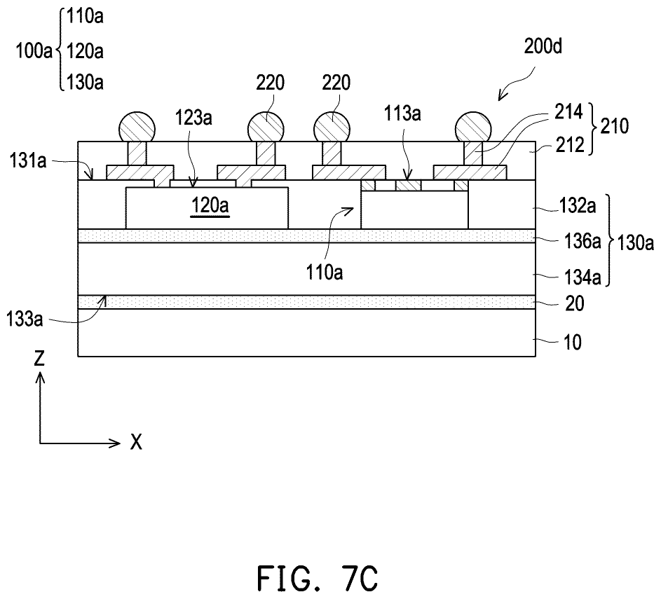

FIG. 7A to FIG. 7C are schematic cross-sectional views of partial steps of a manufacturing method of an electronic device according to another embodiment of the disclosure. Refer to FIG. 7A, regarding the manufacturing method of the electronic device of this embodiment, firstly, a support portion 134a and an adhesive portion 136a disposed on the support portion 134a are provided. Next, a first semiconductor component 110a and a second semiconductor component 120a are disposed on the support portion 134a, wherein the first semiconductor component 110a and the second semiconductor component 120a are fixed on the support portion 134a through the adhesive portion 136a. The first semiconductor component 110a is adjacent to the second semiconductor component 120a. Then, the first semiconductor component 110a and the second semiconductor component 120a fixed on the support portion 134a are disposed on a carrier substrate 10 through an adhesive layer 20. The back surface 111a of the first semiconductor component 110a and the back surface 121a of the second semiconductor component 120a face toward the carrier substrate 10. Next, an encapsulation portion 132a is formed to surround the first semiconductor component 110a and the second semiconductor component 120a. The encapsulation portion 132a is located on the adhesive portion 136a and exposes the active surface 113a of the first semiconductor component 110a. Herein, the encapsulation portion 132a, the support portion 134a, and the adhesive portion 136a define an encapsulation layer 130a. In this embodiment, the material of the encapsulation portion 132a may be the same as the material of the support portion 134a. In another embodiment, the material of the encapsulation portion 132a may be different from the material of the support portion 134a. Furthermore, the coefficient of thermal expansion of the support portion 134a may be smaller than the coefficient of thermal expansion of the encapsulation portion 132a. At this point, the first semiconductor component 110a, the second semiconductor component 120a, and the encapsulation layer 130a may be defined as a package structure 100a.

Next, referring to FIG. 7B, a conductive layer 214 is formed on the first side 131a of the encapsulation layer 130a, and electrically connects the first semiconductor component 110a and the second semiconductor component 120a. In another embodiment, a part of the traces 214b of the conductive layer 214 may simultaneously electrically connect the first semiconductor component 110a and the second semiconductor component 130a as needed, but not limited thereto. Herein, the first thickness T11 of the encapsulation layer 130a is the vertical distance (such as along the Z direction) from the second side 133a to the first side 131a of the encapsulation layer 130a. The first thickness T11 of the encapsulation layer 130a is greater than the second thickness T12 of the first semiconductor component 110a, and the difference between the first thickness T11 and the second thickness T12 is greater than half of the first thickness T11 and less than three times the second thickness T12. In another embodiment, the vertical distance between the back surface 111a of the first semiconductor component 110a and the second side 133a of the encapsulation layer 130a is the fourth thickness T14. In another embodiment, if there is no adhesive layer 136a, the thickness of the support portion 134a is the fourth thickness T14. The fourth thickness T14 is the difference between the first thickness T11 and the second thickness T12, and the fourth thickness T14 is greater than the second thickness T12.

Subsequently, referring to FIG. 7C, an insulation layer 212 is formed on the first side 131a of the encapsulation layer 130a to cover the conductive layer 214, the active surface 113a of the first semiconductor component 110a, and the active surface 123a of the second semiconductor component 120a. The insulation layer 212 is ground to expose the conductive layer 214, wherein the insulation layer 212 and the conductive layer 214 define a circuit layer 210. At this point, the first semiconductor component 110a and the second semiconductor component 120a are disposed between the support portion 134a and the circuit layer 210.

Finally, referring to FIG. 7C, bonding components 220 are formed on the circuit layer 210, wherein the circuit layer 210 is located between the encapsulation layer 130a and the bonding components 220, and the bonding components 220 are electrically connected to the circuit layer 210. The electronic device 200d may be electrically connected to external circuits through the bonding components 220. At this point, the manufacturing of the electronic device 200d is completed.

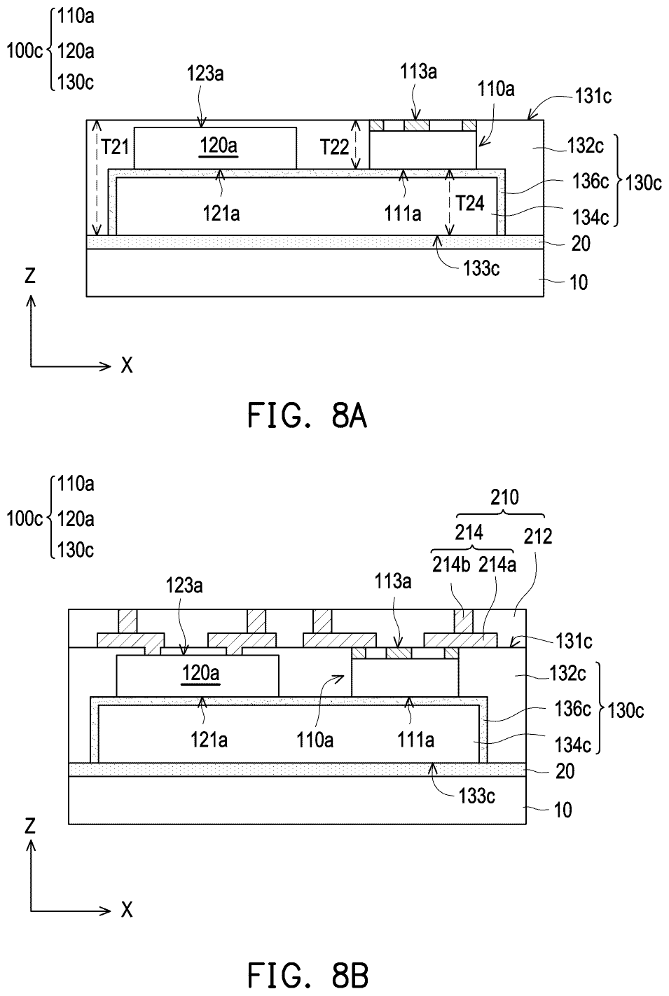

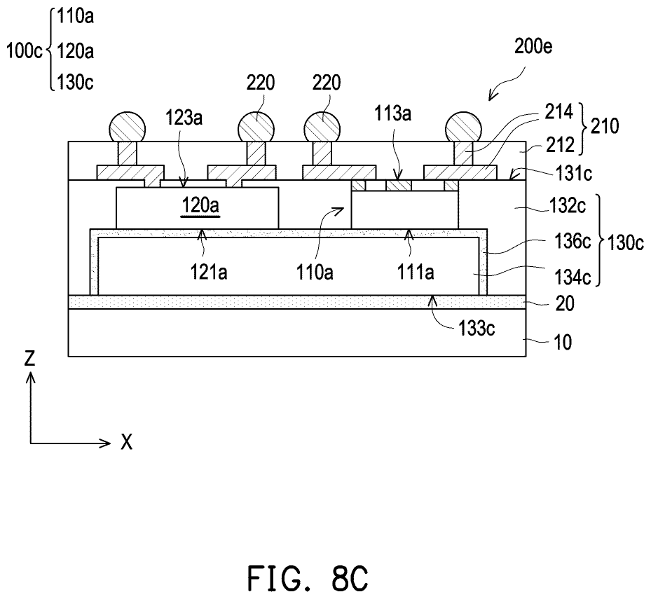

FIG. 8A to FIG. 8C are schematic cross-sectional views of partial steps of a manufacturing method of an electronic device according to another embodiment of the disclosure. Refer to FIG. 8A, regarding the manufacturing method of the electronic device in this embodiment, firstly, a support portion 134c and an adhesive portion 136c disposed on the support portion 134c are provided, wherein the support portion 134c is a patterned structure layer, and the adhesive portion 136c is formed to be conformal with the support portion 134c. Next, a first semiconductor component 110a and a second semiconductor component 120a are provided on the support portion 134c, wherein the first semiconductor component 110a and the second semiconductor component 120a are fixed on the support portion 134c through the adhesive portion 136c. The first semiconductor component 110a is adjacent to the second semiconductor component 120a. Then, the first semiconductor component 110a and the second semiconductor component 120a fixed on the support portion 134c are disposed on a carrier substrate 10 through an adhesive layer 20. The back surface 111a of the first semiconductor component 110a and the back surface 121a of the second semiconductor component 120a face toward the carrier substrate 10. Subsequently, an encapsulation portion 132c is formed to surround the first semiconductor component 110a and the second semiconductor component 120a. The encapsulation portion 132a is located on the adhesive portion 136c and exposes the active surface 113a of the first semiconductor component 110a. Herein, the encapsulation portion 132c, the support portion 134c, and the adhesive portion 136c define an encapsulation layer 130c. In another embodiment, the material of the encapsulation portion 132c may be the same as or different from the material of the support portion 134c. In another embodiment, the coefficient of thermal expansion of the support portion 134c may not be the same as the coefficient of thermal expansion of the encapsulation portion 132b. The coefficient of thermal expansion of the support portion 134c may be smaller than the coefficient of thermal expansion of the encapsulation portion 132c, but not limited thereto. In another embodiment, in the normal direction (e.g., Z direction), the expansion trend of the support portion 134c is different from the expansion trend of the encapsulation portion 132c, for example, opposite. Moreover, the coefficient of thermal expansion of the support portion 134c may be different from the coefficient of thermal expansion of the semiconductor components. At this point, the first semiconductor component 110a, the second semiconductor component 120a, and the encapsulation layer 130c may be defined as a package structure 100c.

Herein, the first thickness T21 of the encapsulation layer 130c is the vertical distance (e.g., along the Z direction) from the second side 133c to the first side 131c of the encapsulation layer 130c. The first thickness T21 of the encapsulation layer 130c is greater than the second thickness T22 of the first semiconductor component 110a, and the difference between the first thickness T21 and the second thickness T22 is greater than half of the first thickness T21 and less than three times the second thickness T22. In another embodiment, the vertical distance between the back surface 111a of the first semiconductor component 110a and the second side 133c of the encapsulation layer 130c is the fourth thickness T24. In another embodiment, the thickness of the support portion 134b is the fourth thickness T24.

Next, referring to FIG. 8B, a conductive layer 214 is formed on the first side 131c of the encapsulation layer 130c to electrically connect the active surface 113a of the first semiconductor component 110a and the active surface 123a of the second semiconductor component 120a. In another embodiment, the conductive layer 214 may electrically connect the first semiconductor component 110a and the second semiconductor component 120a simultaneously according to requirements, but not limited thereto.

Subsequently, referring again to FIG. 8B, an insulation layer 212 is formed on the first side 131c of the encapsulation layer 130c to cover the conductive layer 214, the active surface 113a of the first semiconductor component 110a, and the active surface 123a of the second semiconductor component 120a. The insulation layer 212 is ground to expose the conductive layer 214, wherein the insulation layer 212 and the conductive layer 214 define a circuit layer 210. At this point, the first semiconductor component 110a and the second semiconductor component 120a are disposed between the support portion 134c and the circuit layer 210.

Finally, referring to FIG. 8C, bonding components 220 are formed on the circuit layer 210, wherein the circuit layer 210 is located between the encapsulation layer 130c and the bonding components 220, and the bonding components 220 are electrically connected to the circuit layer 210. The electronic device 200e may be electrically connected to an external circuit through the bonding components 220. At this point, the manufacturing of the electronic device 200e is completed.

In summary, in the embodiments disclosed herein, the first thickness of the encapsulation layer is greater than the second thickness of the first semiconductor component, and the difference between the first thickness and the second thickness is greater than half of the first thickness and less than three times the second thickness. In a top view, the sum of the second area of the first semiconductor component and the third area of the second semiconductor component is greater than half of the first area of the encapsulation layer. By this design, the risk of warping of the package structure causing cracks in the encapsulation layer can be effectively reduced, thereby allowing the electronic device of the present disclosure to have better structural reliability.

Finally, it should be noted that the above embodiments merely serve to illustrate the technical schemes of the disclosure rather than limiting the disclosure. Although the disclosure has been described in detail with reference to the foregoing embodiments, those of ordinary skill in the pertinent art should understand that it is possible to modify the technical schemes described in the foregoing embodiments or equivalently replace some or all of the technical features; and these modifications or replacements do not make the nature of the corresponding technical schemes deviate from the technical schemes of the embodiments provided in the disclosure.

What is claimed is:

1. An electronic device, comprising:
a first semiconductor component;
a second semiconductor component, adjacent to the first semiconductor component;
an encapsulation layer, having a first side, wherein the encapsulation layer surrounds the first semiconductor component and the second semiconductor component; and
a circuit layer, disposed on the first side of the encapsulation layer,
wherein, the encapsulation layer has a first thickness, the first semiconductor component has a second thickness, the first thickness is greater than the second thickness, a difference between the first thickness and the second thickness is greater than half of the first thickness and less than three times the second thickness;
wherein, in a top view, the encapsulation layer has a first area, the first semiconductor component has a second area, the second semiconductor component has a third area, and a sum of the second area and the third area is greater than half of the first area.

2. The electronic device according to claim 1, wherein the second semiconductor component comprises at least one semiconductor unit.

3. The electronic device according to claim 2, wherein a ratio of the coefficient of thermal expansion of the encapsulation layer to a coefficient of thermal expansion of one of the at least one semiconductor unit is between 1.2 and 3.

4. The electronic device according to claim 2, wherein the second semiconductor component further comprises conductive pads and an insulation layer located between the conductive pads.

5. The electronic device according to claim 1, wherein an active surface of the first semiconductor component and an active surface of the second semiconductor component are coplanar with the first side of the encapsulation layer, respectively.

6. The electronic device according to claim 1, wherein a back surface of the first semiconductor component and a back surface of the second semiconductor component are covered by the encapsulation layer.

7. The electronic device according to claim 1, wherein a back surface of the first semiconductor component is exposed outside the encapsulation layer.

8. The electronic device according to claim 1, further comprising:
a heat-conducting structure, wherein the encapsulation layer has a second side opposite to the first side, and the heat-conducting structure is disposed on the second side of the encapsulation layer.

9. The electronic device according to claim 8, wherein a material of the heat-conducting structure comprises a conductive material.

10. The electronic device according to claim 1, wherein the encapsulation layer comprises an encapsulation portion and a support portion, the encapsulation portion surrounds the first semiconductor component and the second semiconductor component, and the first semiconductor component and the second semiconductor component are disposed between the support portion and the circuit layer.

11. The electronic device according to claim 1, further comprising:
a bonding component, disposed on a side of the circuit layer away from the encapsulation layer, wherein the circuit layer is located between the encapsulation layer and the bonding component.

12. The electronic device according to claim 11, wherein a material of the bonding component comprises tin, nickel, gold, silver, palladium, copper, gallium, alloys thereof, or combinations thereof.

13. A manufacturing method of an electronic device, comprising:
providing a first semiconductor component and a second semiconductor component, the first semiconductor component adjacent to the second semiconductor component;
forming an encapsulation layer to surround the first semiconductor component and the second semiconductor component, the encapsulation layer having a first side; and
forming a circuit layer on the first side of the encapsulation layer,
wherein, the encapsulation layer has a first thickness, the first semiconductor component has a second thickness, the first thickness is greater than the second thickness, and a difference between the first thickness and the second thickness is greater than half of the first thickness and less than three times the second thickness;
wherein, in a top view, the encapsulation layer has a first area, the first semiconductor component has a second area, the second semiconductor component has a third area, and a sum of the second area and the third area is greater than half of the first area.

14. The manufacturing method of the electronic device according to claim 13, further comprising:
forming a bonding component on the circuit layer, wherein the circuit layer is located between the encapsulation layer and the bonding component.

15. The manufacturing method of the electronic device according to claim 13, further comprising:
patterning the encapsulation layer and providing a heat-conducting structure, wherein the heat-conducting structure is disposed on a second side of the encapsulation layer opposite to the first side, and directly contacts a back surface of the first semiconductor component.

16. The manufacturing method of the electronic device according to claim 15, wherein the heat-conducting structure comprises a main portion and a plurality of extending portions, wherein the plurality of extending portions connect the main portion and penetrate through the encapsulation layer to contact a back surface of the second semiconductor component.

17. The manufacturing method of the electronic device according to claim 16, wherein an orthographic projection area of the main portion on the encapsulation layer is smaller than an area of the encapsulation layer.

18. The manufacturing method of the electronic device according to claim 16, wherein the heat-conducting structure further comprises a plurality of heat dissipation fin portions, dispersedly disposed on a side of the main portion relatively far from the plurality of extending portions.

19. A package structure, comprising:
a first semiconductor component;
a second semiconductor component, adjacent to the first semiconductor component; and
an encapsulation layer, surrounding the first semiconductor component and the second semiconductor component;
wherein, the encapsulation layer has a first thickness, the first semiconductor component has a second thickness, the first thickness is greater than the second thickness, a difference between the first thickness and the second thickness is greater than half of the first thickness and smaller than three times the second thickness;
wherein, in a top view, the encapsulation layer has a first area, the first semiconductor component has a second area, the second semiconductor component has a third area, and a sum of the second area and the third area is greater than half of the first area.

20. The package structure according to claim 19, wherein the encapsulation layer comprises an encapsulation portion and a support portion, the encapsulation portion surrounds the first semiconductor component and the second semiconductor component, while the first semiconductor component and the second semiconductor component are disposed between the support portion and the circuit layer.
